(19) United States
(12) Patent Application Publication
(10) Pub. No.: US 2022/0071027 A1
(43) Pub. Date: Mar. 3, 2022

(54) ELECTRONIC DEVICE

(71) Applicant: BEIJING XIAOMI MOBILE SOFTWARE CO., LTD., Beijing (CN)

(72) Inventor: Cheng CHANG, Beijing (CN)

(73) Assignee: BEIJING XIAOMI MOBILE SOFTWARE CO., LTD., Beijing (CN)

(21) Appl. No.: 17/242,223

(22) Filed: Apr. 27, 2021

(30) Foreign Application Priority Data
Aug. 31, 2020 (CN) 202010899619.6

(51) Int. Cl. H05K 5/02; H05K 5/00; C09J 9/00

(52) U.S. Cl. CPC H05K 5/02; H05K 1/18; C09J 9/00; H05K 5/0017

(57) ABSTRACT

An electronic device includes: a first member to be adhered; a second member to be adhered; an adhesion-reducing adhesive layer adhered between the first member and the second member. A stickiness of the adhesion-reducing adhesive layer is associated with environmental conditions.

### CROSS-REFERENCE TO RELATED APPLICATIONS

The present application is based upon and claims priority to Chinese Patent Application No. 202010899619.6, filed on Aug. 31, 2020, the content of which is incorporated herein by reference in its entirety for all purposes.

### TECHNICAL FIELD

The present disclosure relates to the technical field of a terminal, and in particular to an electronic device.

### BACKGROUND

For the components which cannot be fastened by a locking member such as a screw in an electronic device, glue is usually used for adhering and fixing the components. In addition, in order to ensure the adhering strength between the components, glue with higher adhesion is usually used for adhering.

However, in the assembling process of the electronic device, it is inevitable that there will be a situation in which disassembly is required for reassembling due to assembly errors or misoperations. Or in the maintenance process, disassembly of the components is also required. If the stickiness of the glue for adhering to the components is too strong, the difficulty for disassembly is increased, and the increase of the disassembling force in the disassembling process may even cause damage to the components, resulting in a decrease in yield.

### SUMMARY

The present disclosure provides an electronic device, to address deficiencies in the related art.

According to a first aspect of the present disclosure, an electronic device is provided. The electronic device includes: a first member to be adhered; a second member to be adhered; and an adhesion-reducing adhesive layer adhered between the first member and the second member, in which a stickiness of the adhesion-reducing adhesive layer is determined by environmental conditions.

It should be understood that the above general description and the following detailed description are merely exemplary and explanatory, and are not intended to limit the present disclosure.

### BRIEF DESCRIPTION OF THE DRAWINGS

The accompanying drawings here, which are incorporated into the description and constitute a part of the description, illustrate examples that conform to the present disclosure and are used together with the description to explain the principles of the disclosure.

FIG. 1 is a schematic diagram of an electronic device according to some examples of the disclosure.

FIG. 2 is a partial schematic diagram of the electronic device of FIG. 1.

FIG. 3 is a cross-sectional schematic diagram of an adhesion-reducing adhesive layer according to some examples of the disclosure.

FIG. 4 is a schematic diagram which shows a connection between a display screen and a housing according to some examples of the disclosure.

FIG. 5 is a schematic diagram which shows a connection between a display screen and an adhesion-reducing adhesive layer according to some examples of the disclosure.

FIG. 6 is a schematic diagram of a display screen according to some examples of the disclosure.

### DETAILED DESCRIPTION

Exemplary embodiments will be described here in detail, and examples thereof are represented in the accompanying drawings. When the following description relates to the accompanying drawings, unless otherwise indicated, the same reference numeral in different accompanying drawings represents the same or similar elements. The implementations described in the following examples do not represent all implementations consistent with the present disclosure. On the contrary, they are merely examples of apparatuses and methods consistent with some aspects of the present disclosure as detailed in the appended claims.

Terms used in the present disclosure are merely for describing specific examples and are not intended to limit the present disclosure. The singular forms “one”, “the”, and “this” used in the present disclosure and the appended claims are also intended to include a multiple form, unless other meanings are clearly represented in the context. It should also be understood that the term “and/or” used in the present disclosure refers to any or all of possible combinations including one or more associated listed items.

Reference throughout this specification to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

It should be understood that although terms “first”, “second”, “third”, and the like are used in the present disclosure to describe various information, the information is not limited to the terms. These terms are merely used to differentiate information of a same type. For example, without departing from the scope of the present disclosure, first information is also referred to as second information, and similarly the second information is also referred to as the first information. Depending on the context, for example, the term “if” used herein may be explained as “when” or “while”, or “in response to . . . , it is determined that”.

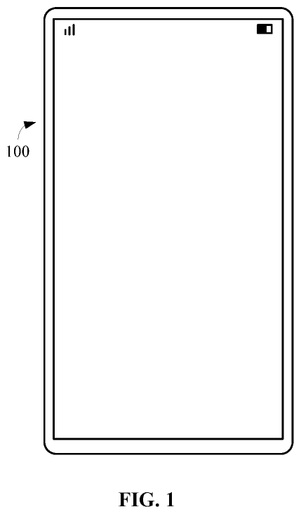

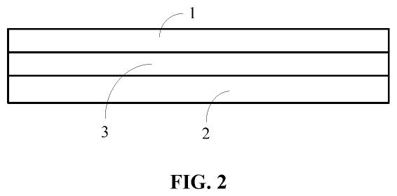

FIG. 1 is a schematic diagram of an electronic device 100 according to some examples of the disclosure, and FIG. 2 is a partial schematic diagram of the electronic device 100 of FIG. 1. As shown in FIG. 1 and FIG. 2, the electronic device 100 may include a mobile phone terminal. Certainly, in other examples, the electronic device 100 may further include various terminal devices, such as a tablet terminal, a computer terminal, a wearable device, an intelligent home device, etc. In the interior of the electronic device 100, in order to realize the connection and fixing between the components arranged adjacent to each other, it is generally necessary to provide a locking member. Moreover, when the components cannot be perforated, it is necessary to use an adhesive tape or the like to realize the connection.

Therefore, as shown in FIG. 2, the electronic device 100 may include a first member 1 to be adhered, a second member 2 to be adhered, and an adhesion-reducing adhesive layer 3 adhered between the first member 1 and the second member 2. The stickiness of the adhesion-reducing adhesive layer 3 is determined by the environmental conditions. In one or more embodiments, the stickiness of the adhesion-reducing adhesive layer 3 is adjustable by applying different environmental conditions. For example, the environmental conditions may include lighting conditions applied to the adhesion-reducing adhesive layer 3. When the light intensity is strong enough, the stickiness of the adhesion-reducing adhesive layer 3 is decreased. While under a normal ambient light condition, the stickiness of the adhesion-reducing adhesive layer 3 is relatively strong, so that the first member 1 and the second member 2 can be firmly adhered. Certainly, in addition to the lighting conditions, the environmental conditions may also include magnetic field conditions, electric field conditions, or vibration conditions of the environment in which the electronic device 100 is located. Alternatively, the environmental conditions may be multiple conditions among the following conditions: lighting conditions, magnetic field conditions, electric field conditions, or vibration conditions, which is not limited in the present disclosure.

The technical solution provided by the examples of the present disclosure may include the following beneficial effects. In the present disclosure, the stickiness of the adhesion-reducing adhesive layer 3 can be improved by improving the environmental conditions, so that when the first member 1 and the second member 2 are disassembled, the stickiness of the adhesion-reducing adhesive layer 3 can be decreased by adjusting the environmental conditions. Therefore, the difficulty for disassembling the first member 1 and the second member 2 can be decreased, while reducing the risk of damage to the first member 1 or the second member 2 due to disassembly therebetween.

For example, the adhesion-reducing adhesive layer 3 may include an optical type adhesion-reducing adhesive layer. The stickiness of the optical type adhesion-reducing adhesive layer is associated with the light intensity within a predetermined wavelength. When the light intensity is strong enough, the stickiness of the optical type adhesion-reducing adhesive layer is decreased, to facilitate disassembling the first member 1 and the second member 2. Moreover, the reduction of the stickiness of the optical type adhesion-reducing adhesive layer under the natural lighting condition can be avoided by setting the wavelength of the light, so that a problem of weak adhesion can be avoided. Herein, the optical type adhesion-reducing adhesive layer may include an ultraviolet light (UV) type adhesion-reducing adhesive layer. The stickiness of the UV type adhesion-reducing adhesive layer is weakened under irradiation of a LED lamp with the wavelength between 365 nm and 385 nm.

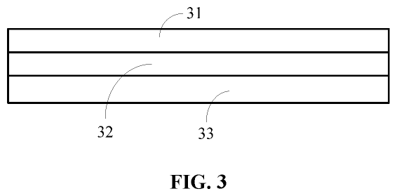

As shown in FIG. 3, the optical type adhesion-reducing adhesive layer may include a first glue layer 31, an intermediate film layer 32 and a second glue layer 33. The intermediate film layer 32 is provided between the first glue layer 31 and the second glue layer 33 for connecting the first glue layer 31 and the second glue layer 33 with each other. The first glue layer 31 may be a UV glue layer, and the second glue layer 33 is different from the UV glue layer. That is, the stickiness of the second glue layer 33 is independent of the irradiation of UV light. The intermediate film layer may include a Polyethylene terephthalate (PET) film layer. When the UV type adhesion-reducing adhesive layer is not adhered to the first member 1 and the second member 2, the UV type adhesion-reducing adhesive layer may further include a release film. The first glue layer 31 and the second glue layer 33 are protected against dust through the release film, so that the stickiness of the first glue layer 31 and the second glue layer 33 is prevented from being decreased.

The electronic device 100 may further include a third member to be adhered and a fourth member to be adhered. A preset adhesive layer may be provided between the third member and the fourth member. The stickiness of the preset adhesive layer is independent of the environmental conditions, which can prevent weakening the stickiness of the preset adhesive layer while weakening the stickiness of the adhesion-reducing adhesive layer 3 by improving the environmental conditions, thereby preventing the insufficient adhering strength between the third member and the fourth member. Alternatively, in other examples, the environmental conditions for reducing the stickiness of the adhesion-reducing adhesive layer 3 are different from the environmental conditions for reducing the stickiness of the preset adhesive layer, which can also prevent weakening the stickiness of the preset adhesive layer while weakening the stickiness of the adhesion-reducing adhesive layer 3 by improving the environmental conditions. Herein, each of the third member and the fourth member may be an internal stacked layer of the first member 1 or the second member 2. Alternatively, each of the third member and the fourth member may be another component other than the first member 1 and the second member 2, which is not limited in the present disclosure.

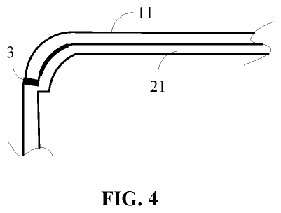

In the above example, as shown in FIG. 4, the first member 1 may include a display screen 11 of the electronic device 100, and the second member 2 may include a housing 21. The adhesion-reducing adhesive layer 3 may be adhered between the display screen 11 and the housing 21. In particular, when the display screen 11 is a flexible display screen, the stickiness of the UV type adhesion-reducing adhesive layer is decreased through the irradiation of the ultraviolet (UV) light, and then the flexible display screen and the housing 21 are disassembled, so that the damage to the flexible display screen in the disassembling process can be greatly reduced. As still shown in FIG. 3, the adhesion-reducing adhesive layer 3 can be adhered between a first surface of the display screen 11 and the housing 21. The first surface of the display screen 11 is a surface of the display screen 11 in a thickness direction of the display screen 11. The first surface of the display screen 11 is adhered to the housing 21 by applying the adhesion-reducing adhesive layer 3, so that the gap between the housing 21 and the display screen 11 of the electronic device 100 can be reduced, or there is even no gap formed between the display screen 11 and the housing 21, thereby improving the dustproof and waterproof property of the electronic device 100. Herein, the adhesion-reducing adhesive layer 3 may be adhered to a portion of the first surface or may be adhered to the entire first surface, which is not limited thereto.

In the example shown in FIG. 4, the adhesion-reducing adhesive layer 3 may also be provided between a second surface of the display screen 11 and the housing 21. The second surface of the display screen is a surface facing toward the interior of the electronic device 100 and provided opposite to a display side of the display screen 11. Since the area of the second surface is relatively large, the adhesive area of the adhesion-reducing adhesive layer 3 may be increased, thereby improving the adhesive strength. The adhesion-reducing adhesive layer 3 may be adhered to a portion of the second surface or attached to the entire second surface, which is not limited thereto. In other examples, the adhesion-reducing adhesive layer 3 may be provided only between the first surface and the housing 21, or only between the second surface and the housing 21, which may be specifically designed as desired and is not limited in the present disclosure.

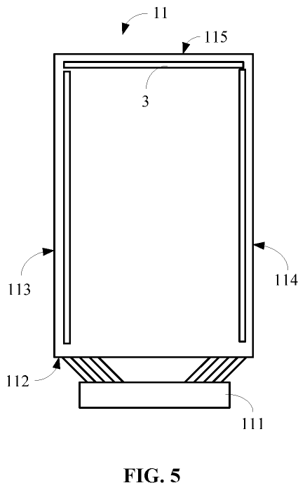

Further, the adhesion-reducing adhesive layer 3 may be adhered to an edge region of the display screen 11. For example, as shown in FIG. 5, the display screen 11 may include a circuit board 111. A data line of the display screen 11 may extend out of an interior of the display screen from a same side edge of the display screen to be electrically connected to the circuit board 111. That is, in the example shown in FIG. 5, the data line may extend out of the display screen from the first edge 112 of the display screen 11 to be electrically connected to the circuit board 111, and the adhesion-reducing adhesive layer 3 may be provided on other side edges of the display screen 11 which are different from the first edge 112. For example, as shown in FIG. 4, the adhesion-reducing adhesive layer 3 may be provided on a second edge 113, a third edge 114 and a fourth edge 115 of the display screen 11, so that the region from which the data line extends out of the display screen may be successively bypassed, thereby avoiding the connection between the adhesion-reducing adhesive layer 3 and the data lines, and avoiding tearing and damage of the data lines. Certainly, in other examples, the adhesion-reducing adhesive layer 3 may be provided on one side edge or two side edges of the second edge 113, the third edge 114 and the fourth edge 115, which is not limited in the present disclosure. The adhesion-reducing adhesive layer 3 at either side edge may be provided in at least one position of a position between the surface adjacent to the display side of the display screen 11 and the housing 21, and a position between the surface opposite to the display side of the display screen 11 and the housing 21.

In the above examples, the strength and the endurance of the display screen 11, as well as the bearing capacity of the internal structure of the display screen 11 to the external force are all relatively weak with respect to the housing 21. Therefore, in order to prevent the adhesion-reducing adhesive layer 3 from driving the internal structure of the display screen 11 into slide when the display screen 11 and the housing 21 are disassembled, the first glue layer 31 may be connected to the display screen 11, and the second glue layer 33 may be connected to the housing 21. In this way, the adhesive strength between the first glue layer 31 and the display screen 11 may be weakened by the irradiation of the UV light, which facilitates reducing the force acting on the display screen 11 and avoiding damage to the display screen 11 due to the disassembly.

Further, understandably, the display screen 11 may include a plurality of stacked layers arranged in sequence in the thickness direction of the display screen 11. The third member may be a stacked layer, and the fourth member may be another stacked layer adjacent to the third member. The two stacked layers adjacent to each other may be adhered by a preset adhesive layer. The stickiness of the preset adhesive layer is independent of the environmental conditions that affect the stickiness of the adhesion-reducing adhesive layer 3. Therefore, when the display screen 11 and the housing 21 are disassembled, the stickiness of the preset adhesive layer can be prevented from being affected by the environmental conditions, which is possible to prevent the force for disassembling the display screen 11 and the housing 21 from acting on the display screen 11 and causing the interior sliding of the display screen 11, thereby preventing the adjacent stacked layers from being misaligned, affecting the display effect and damaging the display screen 11. Herein, the plurality of stacked layers may include one or more of the following layers: a display layer, a protective layer, a graphite layer, a copper foil layer and a flexible film layer.

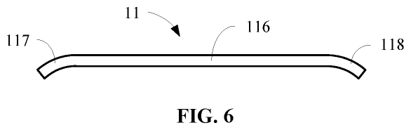

The display screen 11 may include a planar display screen. Alternatively, as shown in FIG. 6, the display screen 11 may include a planar display area 116, a first curved display area 117 and a second curved display area 118. The first curved display area 117 is connected to one side edge of the planar display area 116, and the second curved display area 118 is connected to another side edge of the planar display area 116 opposite to said one side edge. The first curved display area 117 and the second curved display area 118 may be configured for displaying, thereby promoting the display effect and the visual effect. Herein, the adhesion-reducing adhesive layer 3 may be provided in at least one of the first curved display area 117 and the second curved display area 118. For the curved display area, the thickness direction thereof is the same as the radial direction thereof. Therefore, the adhesion-reducing adhesive layer 3 may be provided between a surface of the first curved display area 117 or the second curved display area 118 provided along the radial direction and the housing 21. Alternatively, the adhesion-reducing adhesive layer 3 may also be provided on a surface on the first curved display area 117 or the second curved display area 118 facing toward the interior of the electronic device 100.

A person skilled in the art can easily figure out other implementation solutions of the present disclosure after considering the specification and practicing the invention disclosed here. The present disclosure is intended to cover any variations, functions, or adaptive changes of the present disclosure. These variations, functions, or adaptive changes comply with general principles of the present disclosure and include common knowledge or a common technical means in the technical field that is not disclosed in the present disclosure. The specification and the examples are merely considered to be exemplary, and the actual scope and spirit of the present disclosure are pointed out by the following claims.

It should be understood that the present disclosure is not limited to the precise structure that has been described above and shown in the drawings, and that various modifications and changes can be made without departing from the scope thereof. The scope of the present disclosure is limited only by the appended claims.

What is claimed is:

1. An electronic device, comprising:
a first member to be adhered;
a second member to be adhered; and
an adhesion-reducing adhesive layer adhered between the first member and the second member, wherein a stickiness of the adhesion-reducing adhesive layer is determined by environmental conditions.

2. The electronic device of claim 1, wherein the adhesion-reducing adhesive layer comprises an optical type adhesion-reducing adhesive layer, and a stickiness of the optical type adhesion-reducing adhesive layer is determined by a light intensity within a predetermined wavelength.

3. The electronic device of claim 2, wherein the optical type adhesion-reducing adhesive layer comprises an ultraviolet light (UV) type adhesion-reducing adhesive layer.

4. The electronic device of claim 3, wherein the UV type adhesion-reducing adhesive layer comprises an intermediate film layer, a first glue layer and a second glue layer, wherein the intermediate film layer is disposed between the first glue layer and the second glue layer, the first glue layer is an UV glue layer, and the second glue layer is different from the UV glue layer.

5. The electronic device of claim 1, wherein the electronic device further comprises a third member to be adhered and a fourth member to be adhered, wherein a preset adhesive layer is disposed between the third member and the fourth member; and
wherein a stickiness of the preset adhesive layer is independent of environmental conditions; or a stickiness of the preset adhesive layer is determined by environmental conditions, and environmental conditions for reducing the stickiness of the adhesion-reducing adhesive layer are different from environmental conditions for reducing the stickiness of the preset adhesive layer.

6. The electronic device of claim 1, wherein the first member comprises a display screen of the electronic device, and the second member comprises a housing of the electronic device.

7. The electronic device of claim 6, wherein the adhesion-reducing adhesive layer is disposed between at least a portion of a first surface of the display screen and the housing, wherein the first surface is a surface of the display screen in a thickness direction of the display screen.

8. The electronic device of claim 6, wherein the adhesion-reducing adhesive layer is disposed between at least a portion of a second surface of the display screen and the housing, wherein the second surface is a surface of the display screen opposite to a display side and facing toward interior of the electronic device.

9. The electronic device of claim 6, wherein the display screen further comprises a circuit board, a signal transmission line of the display screen extends out of the display screen from a same side edge of the display screen to be electrically connected to the circuit board; and
wherein the adhesion-reducing adhesive layer is disposed on other side edges of the display screen which are different from said same side edge.

10. The electronic device of claim 6, wherein the display screen comprises a planar display area and at least one curved display area, each curved display area being connected to an edge of the planar display area and curved with respect to the planar display area; and wherein the adhesion-reducing adhesive layer is disposed between the curved display area and the housing.

11. The electronic device of claim 1, wherein the environmental conditions comprise at least one of: a lighting parameter, a magnetic field parameter, an electric field parameter, or a vibration parameter.
